(19) United States
(12) Patent Application Publication
(10) Pub. No.: US 2009/0042523 A1
(43) Pub. Date: Feb. 12, 2009

(54) Multi-media Data Processing Method

(75) Inventors: Chao-Chung Chang, Jhonghe City (TW); Ming-Feng Yu, Tainan City (TW); Ming-Jun Hsiao, Taichung City (TW); Wei-Hao Yuan, Tainan City (TW); Wei-Cheng Chang Chien, Kaohsiung City (TW)

Correspondence Address: Tung & Associates, Suite 120, 838 W. Long Lake Road, Bloomfield Hills, MI, 48302, US

(73) Assignee: Alpha Imaging Technology Corporation

(21) Appl. No.: 11/836,392

(22) Filed: Aug. 9, 2007

(51) Int. Cl. H04B 1/18; H03M 1/12; H03M 13/00

(52) U.S. Cl. 455/131; 341/155; 714/746

(57) ABSTRACT

The present invention discloses a multi-media data processing method for use in an integrated circuit having an error correction circuit, the method comprising the steps of: receiving broadcasted analog data; converting the analog data to digital data; and storing the digital data into a main memory without error correction, wherein the digital data stored in the main memory are subject to error correction only when it is required, but are not subject to error correction if it is not required.

### RELATED APPLICATIONS

The present invention is a continuation-in-part of U.S. Ser. No. 11/581,118 filed by the same applicant on Oct. 13, 2006.

### FIELD OF THE INVENTION

The present invention relates to a multi-media data processing method, and in particular to a method which improves processing speed of broadcasted multi-media data received through a demodulator.

### BACKGROUND OF THE INVENTION

FIG. 1 shows a block diagram of a conventional circuit capable of receiving and processing broadcasted multi-media data. The circuit includes a stand-alone demodulation chip 110 and a stand-alone multi-media processor chip 120. The demodulation chip 110 demodulates received broadcasted multi-media data, and transmits the demodulated data to the multi-media processor chip 120 for further processing, to generate video signals and/or audio signals. These signals are displayed by a display 130 and a speaker 140. The broadcasted multi-media data may be, e.g., wireless Internet data, television signals, etc.

Please refer to the data flow shown in FIG. 2 in conjunction with the circuit structure of FIG. 1. In this conventional structure, external RF (radio frequency) signals are received and processed by an RF tuner 101 for frequency-down conversion. The processed analog signals are transmitted to an ADC (analog-to-digital converter) 111 to be converted to digital signals, and further demodulated by an OFDM demodulator (Orthogonal Frequency Division Multiplexer demodulator) 112. Afterwards, under the control by a controller 113, the digital signals are stored in a demodulator main memory 118 according to the address generated by a data interleaving address generator 114. For error correction purpose, data should be stored and read from different directions; the data interleaving address generator 114 serves the function for determining the addresses to read and store data. For details of memory interleaving, please refer to U.S. Ser. No. 11/581,118 filed by the same applicant. The data stored in the demodulator main memory 118 are subject to error correction by an ECC (error correction circuit) 116, and stored back to the demodulator main memory 118. Thereafter, under the control by the controller 113, the error-corrected data are read out according to the address generated by the data interleaving address generator 114, and transmitted to the multi-media processor chip 120. The multi-media processor chip 120 stores these data in the multi-media main memory 126.

In the multi-media processor chip 120, the data are decoded by a video decoder 122, and outputted via a display controller 128, to be displayed by the display 130. In one instance, the display 130 is a liquid crystal display panel; however it can be any other display device. The data are also decoded by an audio decoder 124, to be displayed by the speaker 140.

The above data flow has the following drawbacks. The data are first subject to complete error correction in the demodulation chip 110, and then stored in the multi-media main memory 126. However, the two chips 110 and 120 communicate with each other through an SPI (serial peripheral interface), which transmits data in a serial manner, i.e., with a narrow bandwidth. Thus, the demodulation chip 110 and the SPI become a bottleneck, decreasing the overall efficiency; it gets even worse if the demodulator main memory 118 has a small capacity. On the other hand, the multi-media processor chip 120 is often provided with a high-capacity memory (the multi-media main memory 126 is generally a high-capacity DRAM), but the capacity of this memory is not sufficiently utilized.

In view of the foregoing, the present invention proposes a multi-media data processing method to overcome the drawbacks in the prior art.

### SUMMARY OF THE INVENTION

A first objective of the present invention is to provide a multi-media data processing method which improves the utilization of the main memory capacity.

A second objective of the present invention is to provide a multi-media data processing method which saves hardware cost.

A third objective of the present invention is to provide a multi-media data processing method which improves overall circuit performance.

To achieve the foregoing objectives, the present invention discloses a multi-media data processing method for use in an integrated circuit having an error correction circuit. The method comprises the steps of: receiving analog data; converting the analog data to digital data; and storing the digital data, without error correction, in a main memory; wherein the digital data stored in the main memory are subject to error correction only when required, but are not subject to error correction when not required.

Preferably, the digital data are transmitted and stored in the main memory in a parallel manner.

The steps in the aforementioned method can be executed in the same integrated circuit, or in different integrated circuits.

For better understanding the objectives, characteristics, and effects of the present invention, the present invention will be described below in detail by illustrative embodiments with reference to the attached drawings.

### BRIEF DESCRIPTION OF THE DRAWINGS

FIG. 1 schematically shows a conventional circuit capable of receiving and processing broadcasted multi-media data.

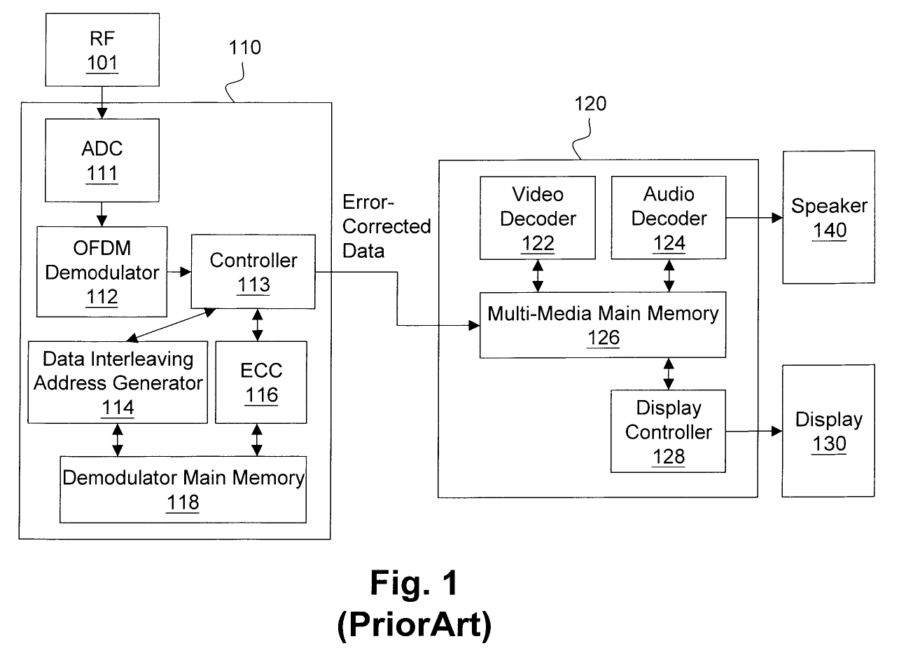

FIG. 2 shows the data flow in the conventional circuit of FIG. 1.

FIG. 3 schematically shows the hardware structure of a first preferred embodiment of the present invention.

FIG. 4 schematically shows the hardware structure of a second preferred embodiment of the present invention.

FIG. 5 shows the data flow according to the present invention.

### DETAILED DESCRIPTION OF THE PREFERRED EMBODIMENT

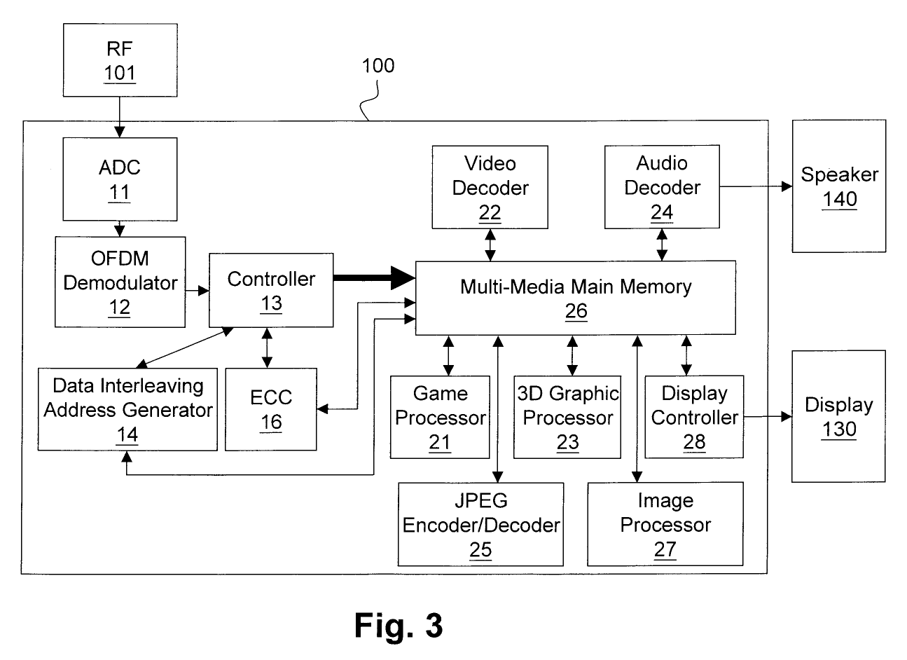

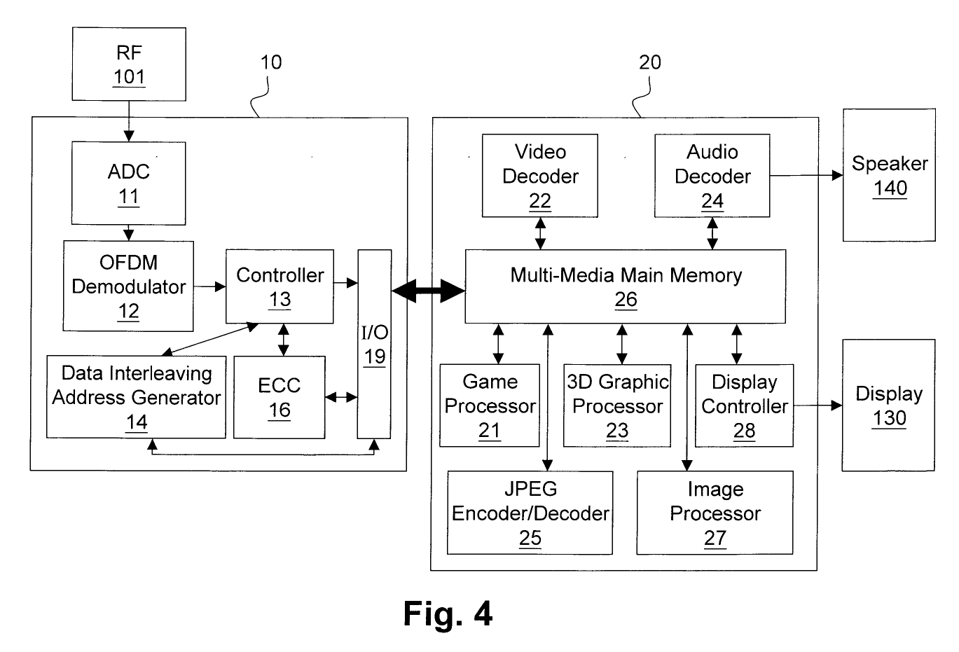

FIG. 3 schematically shows a preferred embodiment according to the present invention. In this embodiment, for better illustrating the difference between the present invention and prior art, almost all circuit components (except the RF tuner 101) are integrated in one integrated circuit chip 100. However, the present invention is not limited to this, but instead can be achieved by two different integrated circuit chips 10 and 20 (except the RF tuner 101), as shown in FIG. 4. In the embodiment of FIG. 3, the RF tuner 101 receives and processes external RF signals for frequency-down conversion. The processed analog signals are transmitted to an ADC 11 to be converted to digital signals, and further demodulated by an OFDM demodulator 12. Afterwards, under the control by a controller 13, the digital signals are directly stored in a multi-media main memory 26, without being subject to error correction first. For better efficiency, the controller 13 and the multi-media main memory 26 communicate with each other via high bandwidth parallel transmission instead of SPI, as shown by the thick arrow in the figure.

The multi-media main memory 26 can be any type of memory, decided by cost and other considerations. Because data are directly stored in the multi-media main memory 26 without error correction, the capacity of the multi-media main memory 26 can be fully utilized. Since the capacity of the multi-media main memory 26 is fully utilized, the demodulator main memory 118 is no more required, and thus it is omitted as shown in the left side of the figure.

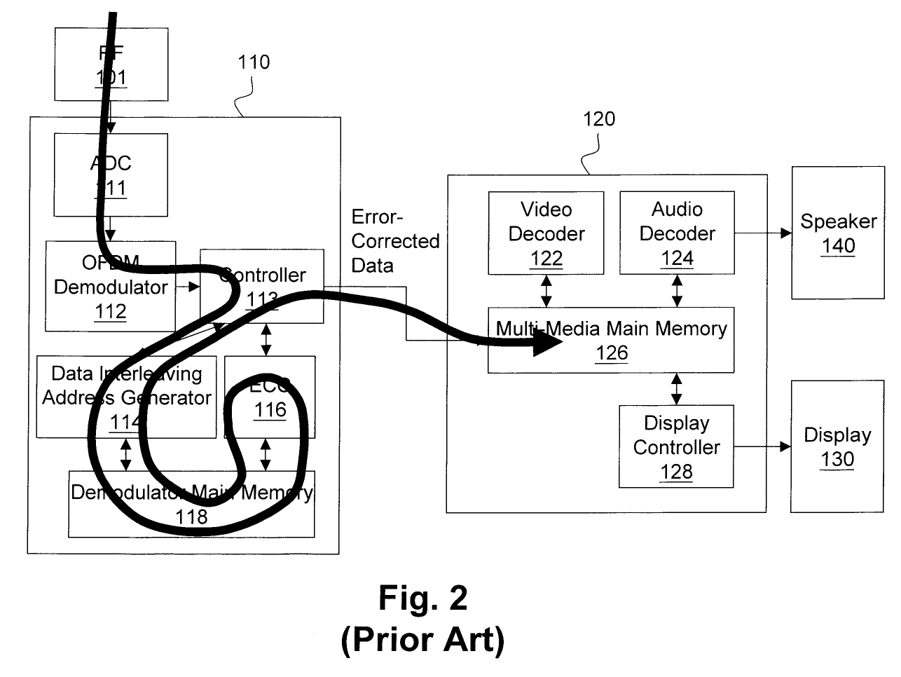

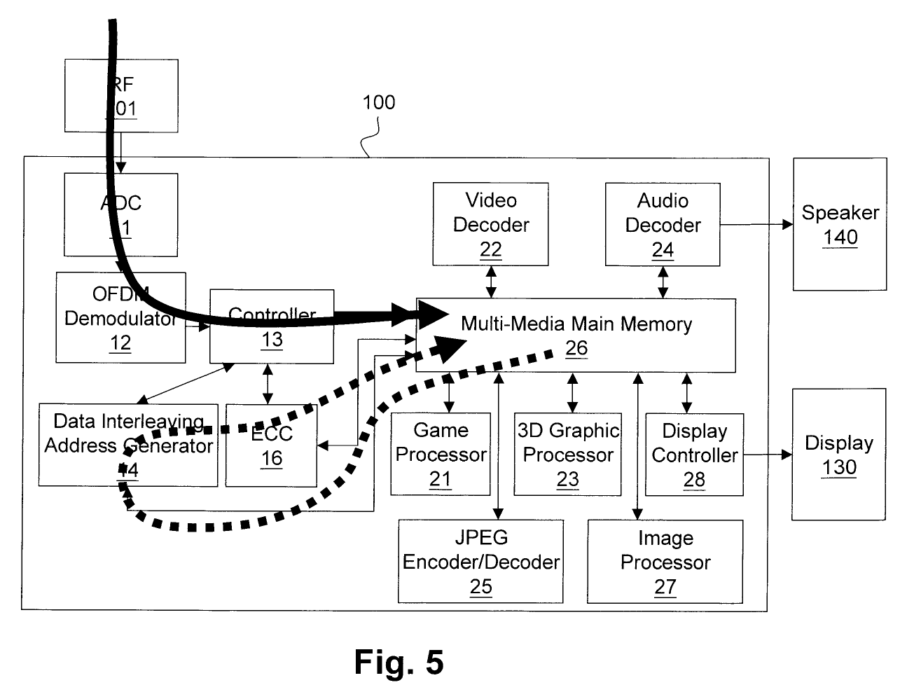

As shown by comparing FIGS. 2 and 5, the data flow in the present invention is much simpler and neat. All data that have been analog-to-digital converted are directly transmitted to the multi-media main memory 26; thereafter, only when required, these data are corrected by an ECC 16. Data do not have to be corrected when it is not required; such conditions where data do not have to be corrected include: 1) when the original broadcasted data are not encoded with error correction code (because of transmission speed concern, or because the broadcasting channel is stable, or for other reasons so that error correction encoding is not required); 2) when the receiver side determines that the broadcasting channel is stable that there is no significant error in transmission. Thus, it saves the processing time of the ECC 16, and improves the performance of the ECC 16 and the overall efficiency of the circuit.

In the embodiments of FIGS. 3 and 4, preferably, the circuit may further include a game processor 21 to provide interactive games to a user; a 3D (3-dimensional) graphic processor 23 for processing 3D graphics; a JPEG encoder/decoder 25 for compressing/decompressing video or graphic files; and an image processor 27 for processing display contrast, color, brightness, etc.

By comparing the present invention with prior art, it can be readily seen that the data flow in the present invention is much simpler, and it saves hardware cost and improves efficiency.

The features, characteristics and effects of the present invention have been described with reference to its preferred embodiments, for illustrative purpose rather than limiting the scope of the invention. Various other substitutions and modifications will occur to those skilled in the art, without departing from the spirit of the present invention. For example, between two circuit blocks shown in the embodiments, one may insert a circuit device that does not substantially affect the primary function of the overall circuit; the circuit blocks can be integrated in a manner other than the embodiments shown in FIGS. 3 and 4; depending on the received broadcasted signals, the demodulator 12 is not necessarily an OFDM demodulator; the display can be any display device other than a liquid crystal display panel; the RF tuner 101 is not necessarily a stand-alone device, but may be integrated with other circuit blocks. Therefore, all such substitutions and modifications are intended to be embraced within the scope of the invention as defined in the appended claims.

What is claimed is:

1. A multi-media data processing method for use in an integrated circuit having an error correction circuit, the method comprising the steps of:
receiving analog data;
converting the analog data to digital data; and
storing the digital data, without error correction, in a main memory;
wherein the digital data stored in the main memory are subject to error correction only when required, but are not subject to error correction when not required.

2. The multi-media data processing method as claimed in claim 1, wherein all the steps are executed in the same integrated circuit.

3. The multi-media data processing method as claimed in claim 1, wherein the step converting the analog data to digital data is executed by a first circuit which does not belong to the same integrated circuit as the main memory.

4. The multi-media data processing method as claimed in claim 1, wherein the digital data are stored in the main memory via parallel transmission.

5. The multi-media data processing method as claimed in claim 2, wherein the integrated circuit further includes one or more of: a game processor, a 3D graphic processor, a JPEG encoder/decoder, and an image processor.

6. The multi-media data processing method as claimed in claim 3, wherein the integrated circuit further includes one or more of: a game processor, a 3D graphic processor, a JPEG encoder/decoder, and an image processor.

7. The multi-media data processing method as claimed in claim 1, further comprising the step of: receiving RF broadcasted data, and performing frequency-down conversion of the received data to obtain the analog data.

8. The multi-media data processing method as claimed in claim 1, further comprising the step of: demodulating the digital data that have been converted from the analog data.
